(19) United States
(12) Patent Application Publication
(10) Pub. No.: US 2013/0221379 A1
(43) Pub. Date: Aug. 29, 2013

(54) PHOTO COUPLER

(71) Applicant: KABUSHIKI KAISHA TOSHIBA, (US)

(72) Inventor: Takayuki SAITO, Fukuoka-ken (JP)

(73) Assignee: KABUSHIKI KAISHA TOSHIBA, Tokyo (JP)

(21) Appl. No.: 13/779,152

(22) Filed: Feb. 27, 2013

(30) Foreign Application Priority Data
Feb. 29, 2012 (JP) 2012-043099

(51) Int. Cl. H01L 31/173

(52) U.S. Cl. CPC H01L 31/173
USPC 257/82

(57) ABSTRACT

According to one embodiment, in a photo coupler, a light emitting device is mounted on a first mount-bed and electrically connected to a pair of first leads. A light receiving device is mounted on a second mount-bed, is electrically connected to a pair of second leads, and receives light emitted from the light emitting device by reflection. A first resin has a first refractive index and covers the light emitting device and the light receiving device. An opaque container has a concave portion to store the light emitting device and the light receiving device, and reflects the light emitted from the light emitting device at the concave portion. A second resin has a second refractive index lower than the first refractive index and fills a space between the first resin and the concave portion of the opaque container. A lid seals the concave portion of the opaque container.

### CROSS REFERENCE TO RELATED APPLICATION

This application is based upon and claims the benefit of priority from the prior Japanese Patent Application No.2012-043099 filed on Feb. 29, 2012, the entire contents of which are incorporated herein by reference.

### FIELD

Embodiments described herein relate generally to a photo coupler.

### BACKGROUND

In the background art, some photo couplers having a light emitting device and a light receiving device are configured to receive light from the light emitting device by reflection.

In the photo couplers, the light emitting device and the light receiving device are mounted on a pair of lead frames and electrically connected with the pair of lead frames. The pair of lead frame is separately laterally disposed and is flush with each other. The light emitting device and the light receiving device are covered by a translucent resin which has a shape of dome and acts as a light guide. The light guide is covered with an opaque resin which has a rectangular shape and is a container. The light emitted from the light emitting device is reflected with an interface between the translucent resin and the opaque resin and is guided to the light receiving device.

A light coupling efficiency between the light emitting device and the light receiving device depends on the shape of the translucent resin which covers the light emitting device and the light receiving device, and light extraction efficiency from the light emitting device to the translucent resin.

Therefore, it is a problem that the light coupling efficiency is changed due to the fluctuation of the shape of the translucent resin. Further, it is a problem that the light extraction efficiency from the light emitting device is not sufficient due to the difference in refractive index between the light emitting device and the translucent resin.

### BRIEF DESCRIPTION OF THE DRAWINGS

FIGS. 1A to 1C are views illustrating a photo coupler according to a first embodiment;

FIGS. 2A to 2C, 3A to 3C and 4A to 4C are cross-sectional views illustrating steps of manufacturing the photo coupler in sequential order according to the first embodiment;

FIG. 5 is a cross-sectional view illustrating a photo coupler according to a second embodiment; and

FIG. 6 is a cross-sectional view illustrating a main step of manufacturing the photo coupler according to the second embodiment.

### DETAILED DESCRIPTION

According to one embodiment, in a photo coupler, a light emitting device is mounted on a first mount-bed and electrically connected to a pair of first leads. A light receiving device is mounted on a second mount-bed, is electrically connected to a pair of second leads, and receives light emitted from the light emitting device by reflection. A first resin has a first refractive index and covers the light emitting device and the light receiving device. An opaque container has a concave portion to store the light emitting device and the light receiving device, and reflects the light emitted from the light emitting device at the concave portion. A second resin has a second refractive index lower than the first refractive index and fills a space between the first resin and the concave portion of the opaque container. A lid seals the concave portion of the opaque container to store the light emitting device and the light receiving device.

Hereinafter, embodiments will be described with reference to the drawings. In the drawings, same reference characters denote the same or similar portions.

### First Embodiment

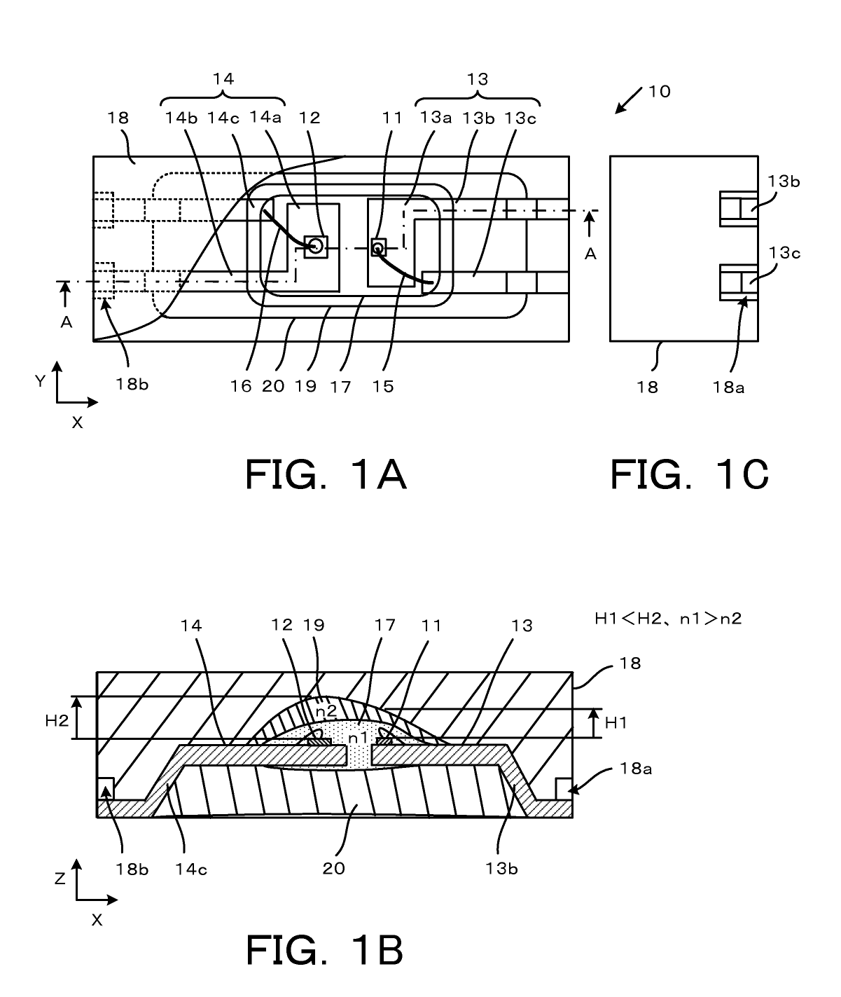

A photo coupler of a first embodiment will be described with reference to FIGS. 1A to 1C. FIGS. 1A to 1C are views illustrating the photo coupler of the first embodiment. FIG. 1A is a plan view in which a portion of the photo coupler is cut and an inside of the photo coupler is exposed. FIG. 1B is a cross-sectional view taken along the line A-A in FIG. 1A. FIG. 1C is a side view thereof.

The photo coupler of the first embodiment has a light emitting device and a light receiving device. The photo coupler is configured so that the light receiving device receives light emitted from the light emitting device by reflection. The photo coupler is what is called a reflection mode photo coupler.

As shown in FIGS. 1A to 1C, in a photo coupler 10, a light emitting device 11 is mounted on a lead frame 13 and electrically connected to the lead frame 13. A light receiving device is mounted on a lead frame 14 and electrically connected to the lead frame 14.

The light emitting device 11 is a light emitting diode of GaAlAs system which emits near infrared light (approximately 900 nm), for example. The light receiving device is a silicon photo diode which has detection sensitivity in near infrared light, for example. The light emitting device 11 has an upper surface and a lower surface which are opposed to each other. An upper electrode (not shown) is provided on the upper surface and a lower electrode (not shown) is provided on the lower surface, so that an electric current flows from the upper surface to the lower surface. An electric current flow of the light receiving device 12 is the same as that of the light emitting device 11.

The lead frame 13 has a mount-bed (a first mount-bed) 13a and a pair of leads (first leads) 13b, 13c. The lead 13b extends from the mount-bed 13a toward one end side (direction of +X in FIG. 1A). The lead 13c is separated from the mount-bed 13a and extends in a direction approximately parallel to the lead 13b. End portions of the leads 13b, 13c are aslant bent in the direction of −Z and also bent in the direction of +X.

The lead frame 14 has a mount-bed (a second mount-bed) 14a and a pair of leads (second leads) 14b, 14c. The lead 14b extends from the mount-bed 14a toward another end side (direction of −X in FIG. 1A). The lead 14c is separated from the mount-bed 14a and extends in a direction approximately parallel to the lead 14b. End portions of the leads 14b, 14c are aslant bent in the direction of −Z and also bent in the direction of −X.

The mount-bed 13a faces the mount-bed 14a and is flush with the mount-bed 14a. The portions of the leads 13b, 13c which are bent and extend in the direction of +X are flush with the portions of the leads 14b, 14c which are bent and extend in the direction of −X.

The light emitting device 11 is placed on the mount-bed 13a with a conductive adhesive interposed therebetween. A lower electrode of the light emitting device 11 is electrically connected to the lead 13b via the conductive adhesive. An upper electrode of the light emitting device 11 is electrically connected to the lead 13c via a wire 15. A lower electrode of the light receiving device 12 is electrically connected to the lead 14b via the conductive adhesive. An upper electrode of the light receiving device 12 is electrically connected to the lead 14c via a wire 16.

A first translucent resin (a first resin) 17 which has a first refractive index n1 to the light emitted from the light emitting device 11 covers the light emitting device 11 on the lead frame 13 and the light receiving device 12 on the lead frame 14.

The first translucent resin 17 also covers the wire 15 and the wire 16. The first translucent resin 17 is a silicone resin having the first refractive index n1 of approximately 1.53, for example.

The light emitting device 11 and the light receiving device 12 which are covered with the first translucent resin 17 are stored in a concave portion of an opaque container 18. The opaque container 18 is a molded body of black epoxy resin.

The opaque container 18 has a first concave portion, a second concave portion, a pair of first grooves and a pair of second grooves. The first concave portion has a section of a trapezoidal shape in the direction of X and a section of a rectangular shape in the direction of Y. The second concave portion is a shape of dome provided at a central portion of the first concave portion. The pair of first grooves extends from the first concave portion to one side of the opaque container 18. The pair of second grooves extends from the first concave portion to another side of the opaque container 18. The first concave portion, the second concave portion, the pair of first grooves and the pair of second grooves are not shown.

The first concave portion has a flat bottom, a first sloping surface along the portions of the leads 13b, 13c aslant bent in the direction of −Z and a second sloping surface along the portions of the leads 14b, 14c aslant bent in the direction of −Z.

A shape of the second concave portion is determined so that the light emitted from the light emitting device 11 is reflected with an inner surface of the dome and enters the light receiving device 12 efficiently. A height H1 from the light emitting device 11 to the inner surface of the second concave portion is set up lower than a height H2 from the light receiving device 12 to the inner surface of the second concave portion. Therefore, the section of the second concave portion in the direction of X is asymmetrical to a median line of the light emitting device 11 and the light receiving device 12.

The width of the first grooves is slightly larger than that of the leads 13b, 13c. The width of the second grooves is slightly larger than that of the leads 14b, 14c.

The portions of the leads 13b, 13c which extend from the side of mount-bed 13a are in contact with the flat bottom of the first concave portion. The portions of the leads 14b, 14c which extend from the side of mount-bed 14a are in contact with the flat bottom of the first concave portion. The portions of the leads 13b, 13c which are aslant bent in the direction of −Z are in contact with the first sloping surface. The portions of the leads 14b, 14c which are aslant bent in the direction of −Z are in contact with the second sloping surface.

The portions of the leads 13b, 13c which are bent in the direction of +X fit the first grooves. The portions of the leads 14b, 14c which are bent in the direction of −X fit the second grooves.

Thereby, the light emitting device 11 and the light receiving device 12 which are covered with the first translucent resin 17 are stored in the second concave portion of the opaque container 18. The first translucent resin 17 is not in contact with the second concave portion of the opaque container 18.

A second translucent resin (a second resin) 19 having a second refractive index n2 lower than the first refractive index n1 fills a space between the first translucent resin 17 and the second concave portion of the opaque container 18. The second translucent resin 19 is a silicone resin having the second refractive index n2 of 1.41, for example.

As an opaque lid (a lid) 20 to seal the second concave portion of the opaque container 18, a black epoxy resin fills the first concave portion of the opaque container 18.

Therefore, the portions of the leads 13b, 13c which extend in the direction of +X after being aslant bent in the direction of −Z are exposed at a bottom of the opaque container 18 (which is the side of the opening of the first concave portion) and a side of the opaque container 18. The portions of the leads 14b, 14c which extend in the direction of −X after being aslant bent in the direction of −Z are exposed at the bottom of the opaque container 18 and the side of the opaque container 18. That is, each of end portions of the leads 13b, 13c, 14b and 14c has an upper surface, a lower surface opposed to the upper surface and an edge, the lower surface is exposed at the bottom of the opaque container 18, the edge is exposed at the side of the opaque container 18, and the bottom of the opaque container 18 is the side of the opening of the first concave portion of the opaque container 18.

Also, the opaque container 18 has a cutout portion 18a at one side and a cutout portion 18b at another side. The cutout portion 18a exposes the edges of the lead 13a, 13b. The cutout portion 18b exposes the edges of the lead 14a, 14b. When the photo coupler 10 is mounted on a board, it is easy to visually observe a solder fillet through the cut outs 18a, 18b. That is, the cutout portions 18a, 18b to partly expose the upper surface are provided at the both sides of the opaque container 18.

The photo coupler 10 mentioned above is configured to improve a light extraction efficiency of the light emitting device 11 and a light detection sensitivity of the light receiving device 12 so as to raise a light coupling efficiency between the light emitting device 11 and the light receiving device 12.

The light emitting device 11 is doubly covered with the first translucent resin 17 having the first refractive index n1 and the second translucent resin 19 having the second refractive index n2 lower than the first refractive index n1. Since the refractive index between the light emitting device 11 and the second concave portion of the opaque container 18 gradually changes, the light extracted from the light emitting device 11 can increase.

It is assumed that gallium arsenide has refractive index of 3.5, an angle of total reflection at an interface between the light emitting device 11 and the first translucent resin 17 is 25.9° and a normal incident reflectivity is 0.15.

On the other hand, it is assumed that the light emitting device 11 is directly covered with the second translucent resin 19, an angle of total reflection at an interface between the light emitting device 11 and the second translucent resin 19 is 23.7° and a normal incident reflectivity is 0.18.

Consequently, it is possible to improve the light extraction efficiency of the light emitting device 11 by the first translucent resin 17 between the light emitting device 11 and the second translucent resin 19.

The shape of the second concave portion is set up so that light which is emitted from the light emitting device 11, is reflected with the inner surface of the second concave portion and enters approximately perpendicularly the upper surface (a pn junction surface which is a light receiving surface) of the light receiving device 12 is increased.

It is preferable to lessen curvature of the side of the light emitting device 11 and enlarge curvature of the side of the light receiving device 12 in accordance with a distance between the light emitting device 11 and the light receiving device 12, a depth of the second concave portion and the like, for example.

Therefore, the shape of the second concave portion is a shape in which the height H1 from the light emitting device 11 to the inner surface of the second concave portion is smaller than the height H2 from the light receiving device 12 to the inner surface of the second concave portion.

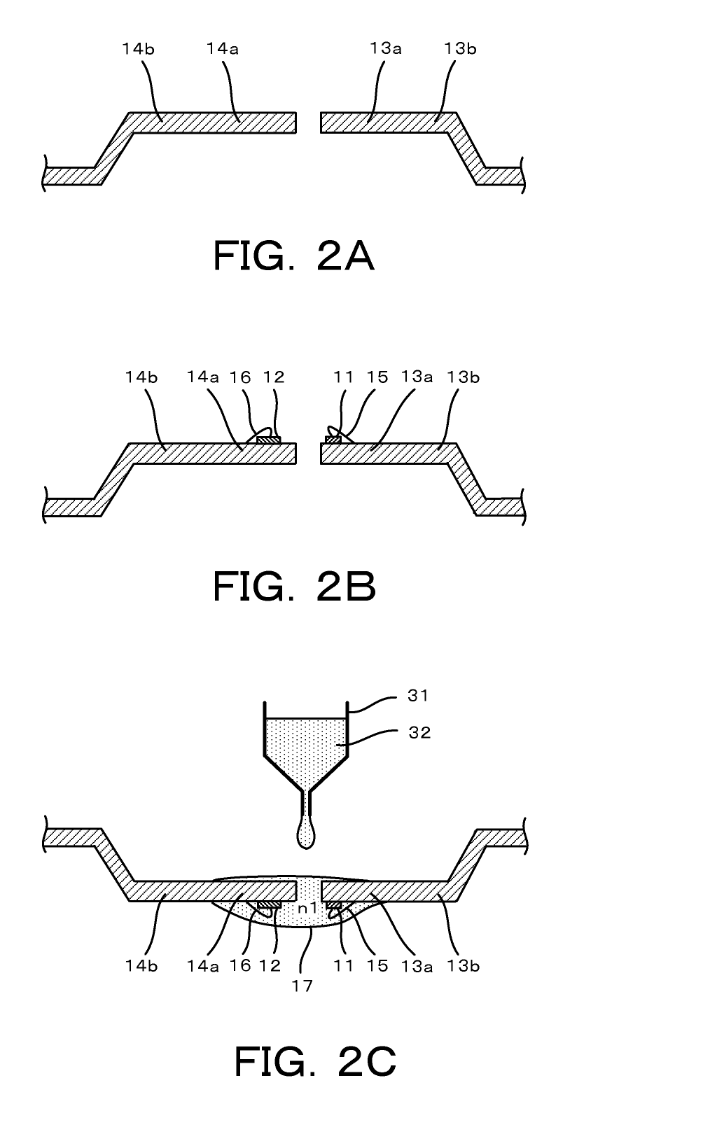

A method of manufacturing the photo coupler 10 is described. FIGS. 2A to 2C, 3A to 3C, 4A to 4C are cross-sectional views illustrating steps of manufacturing the photo coupler 10 in sequential order.

As shown in FIG. 2A, the lead frames 13, 14 are prepared. The lead frames 13, 14 are a portion of a lead frame which is made by repeatedly forming the lead frames 13, 14 as one unit.

As shown in FIG. 2B, the light emitting device 11 is mounted on the mount-bed 13a via the conductive adhesive (not shown). The light receiving device 12 is mounted on the mount-bed 14a via the conductive adhesive (not shown).

The bonding of the wire 15 is performed to the light emitting device 11 and the lead 13c. The bonding of the wire 16 is performed to the light receiving device 12 and the lead 14c.

As shown in FIG. 2C, after reversing the lead frames 13, 14, a first silicone resin 32 in liquid form is dropped using a dispenser 31. When dropped, the first silicone resin 32 becomes approximately a shape of dome in accordance with surface tension and one's own weight. Therefore, the light emitting device 11 mounted on the lead frame 13 and the light receiving device 12 mounted on the lead frame 14 are covered with the first silicone resin 32.

Simultaneously, it is preferable to lean the lead frames 13, 14 so that a thickness of the first silicone resin 32 of the side of the light receiving device 12 becomes larger than a thickness of the first silicone resin 32 of the side of the light emitting device 11. It is performed in order that the shape of the first silicone resin 32 makes similar to the shape of the second concave portion of the opaque container 18.

It is also preferable to cover the wires 15, 16 with the first silicone resin 32. In case where the wires 15, 16 protrude from the first silicone resin 32, it prevents bubbles from adhering to the wires 15, 16 while filling the space between the first translucent resin 17 and the second concave portion of the opaque container 18 with the second translucent resin 19.

Since leak current flows between the light emitting device 11 and the light receiving device 12 when there are bubbles which adhere the wire 15, 16, so that a withstand voltage of the photo coupler 10 is decreased. A reliability of the photo coupler 10 might become impaired.

A cure treatment of the first silicone resin 32 which covers the light emitting device 11 and the light receiving device 12 is performed at a prescribed temperature. Thereby, the first translucent resin 17 which has the refractive index n1 and covers the light emitting device 11 and the light receiving device 12 is obtained.

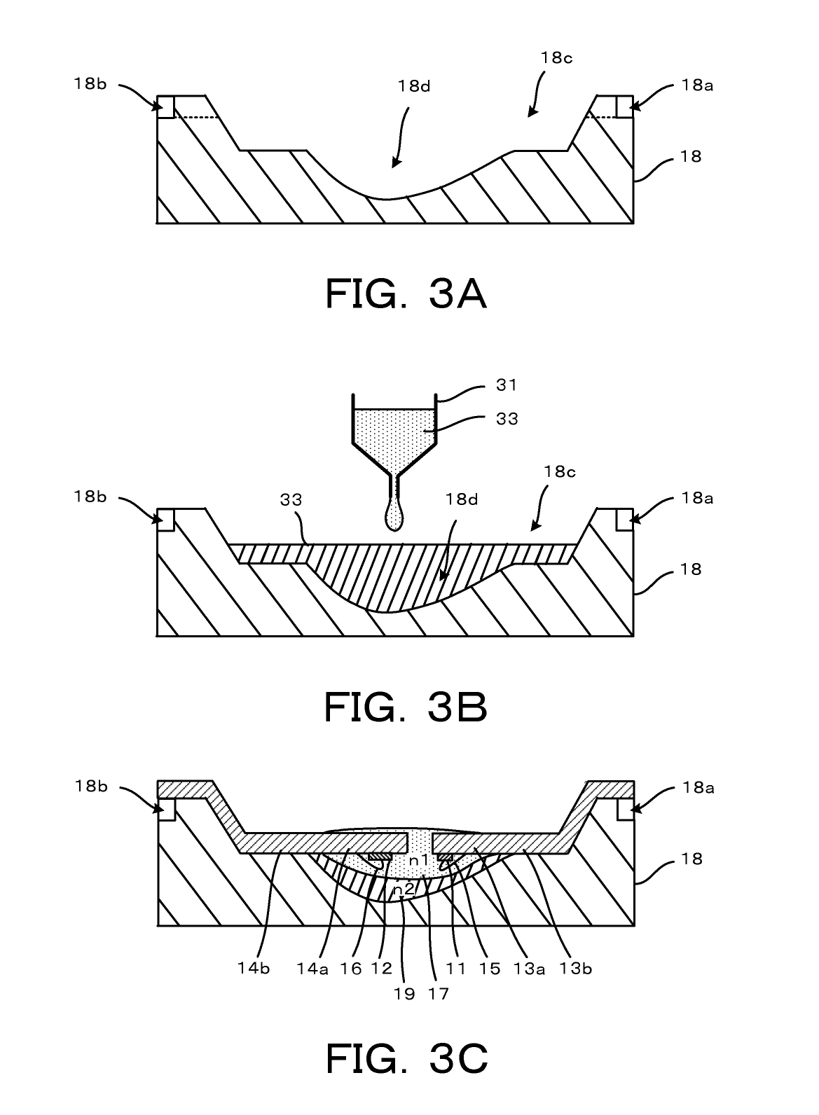

As shown in FIG. 3A, the opaque container 18 which is formed by molding an opaque resin in advance is prepared. The opaque container 18 is a portion of a molded body in which the opaque container 18 is repeatedly formed in accordance with the one unit of the lead frames 13, 14.

As described above, the opaque container 18 has the first concave portion 18c and the second concave portion 18d. The first concave portion 18c has the section of the trapezoidal shape in the direction of X and the section of the rectangular shape in the direction of Y. The second concave portion 18d has the section of the shape of asymmetrical dome in the direction of X provided at the central portion of the first concave portion 18c.

As shown in FIG. 3B, a second silicone resin 33 in liquid form is dropped in the second concave portion 18d of the opaque container 18 using the dispenser 31. The second silicone resin 33 is filled from the second concave portion 18d to a middle of the first concave portion 18c.

As shown in FIG. 3C, the lead frames 13, 14 reversed up and down is inserted in the first concave portion 18c of the opaque container 18. The portions of the leads 13b, 13c which extend from the mount-bed 13a are in contact with the flat bottom of the first concave portion 18c. Similarly, the portions of the leads 14b, 14c which extend from the mount-bed 14a are in contact with the flat bottom of the first concave portion 18c. The portions of the leads 13b, 13c which are aslant bent in the direction of −Z is in contact with the first sloping surface of the first concave portion 18c. The portions of the leads 13b, 13c which are bent in the direction of +X after being aslant bent in the direction of −Z fit the first grooves. Similarly, the portions of the leads 14b, 14c which are aslant bent in the direction of −Z is in contact with the second sloping surface of the first concave portion 18c. The portions of the leads 13b, 13c which are bent in the direction of −X after being aslant bent in the direction of −Z fit the second grooves.

Thereby, the light emitting device 11 and the light receiving device 12 which are respectively mounted on the lead frames 13, 14 and covered with the first translucent resin 17 are stored in the second concave portion 18d and covered with the second silicone resin 33 in liquid form.

A cure treatment of the second silicone resin 33 in liquid form is performed at a prescribed temperature. Thereby, the second translucent resin 19 which has the refractive index n2 and fills the space between the first translucent resin 17 and the second concave portion 18d is obtained.

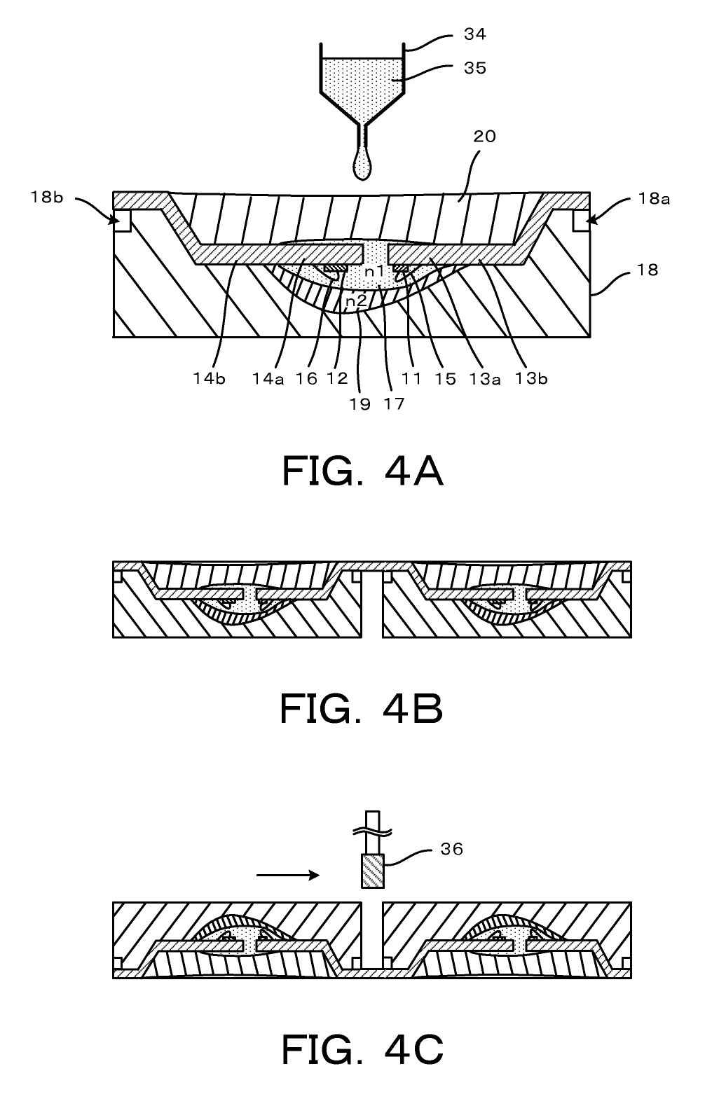

As shown in FIG. 4A, a black resin 35 in liquid form is dropped in the first concave portion 18c of the opaque container 18 using a dispenser 34 so as to fill the first concave portion 18c.

A cure treatment of the black resin 35 in liquid form is performed at a prescribed temperature. Thereby, the opaque lid 20 to seal the second concave portion 18d which stores the light emitting device 11 and the light receiving device 12 is obtained.

As shown in FIG. 4B, the multiple photo couplers 10 are connected in series in the direction of X by the lead frame which is made by repeatedly forming the lead frames 13, 14 as one unit.

As shown in FIG. 4C, a portion between the lead frames 13, 14 which are continuous is cut using a blade 36, for example. As a result, the photo coupler 10 shown in FIG. 1 is obtained.

As described above, in the photo coupler 10 of the embodiment, the first translucent resin 17 having the first refractive index n1 covers the light emitting device 11 mounted on the lead frame 13 and the light receiving device 12 mounted on the lead frame 14.

The light emitting device 11 mounted on the lead frame 13 and the light receiving device 12 mounted on the lead frame 14 are stored in the second concave portion 18d of the opaque container 18. The second concave portion 18d is the shape of asymmetrical dome in which the height H1 from the light emitting device 11 to the inner surface of the second concave portion 18d is lower than the height H2 from the light receiving device 12 to the inner surface of the second concave portion 18d of the opaque container 18.

The second translucent resin 19 fills the space between the first translucent resin 17 and the second concave portion 18d of the opaque container 18.

As a result, the light extraction efficiency from the light emitting device 11 is increased and the light detection efficiency also is increased. Therefore, a photo coupler with high optical coupling efficiency is obtained.

The description has been given for the opaque container where the first translucent resin 17 and the second translucent resin 19 are silicone resins which differ in a quality of material. However, silicone resins which are same in a quality of material are available. It is possible to generate a difference of refractive index between the silicone resins which are same in the quality of material when being subjected to cure treatment at different temperatures.

A lead frame which is made by repeatedly forming the lead frames 13, 14 as one unit in the direction of X and in the direction of Y is available. In the step shown in FIG. 4C, “two or more in one” type photo coupler is obtained when the lead frame is cut with a spacing of the two or more units in the direction of Y.

### Second Embodiment

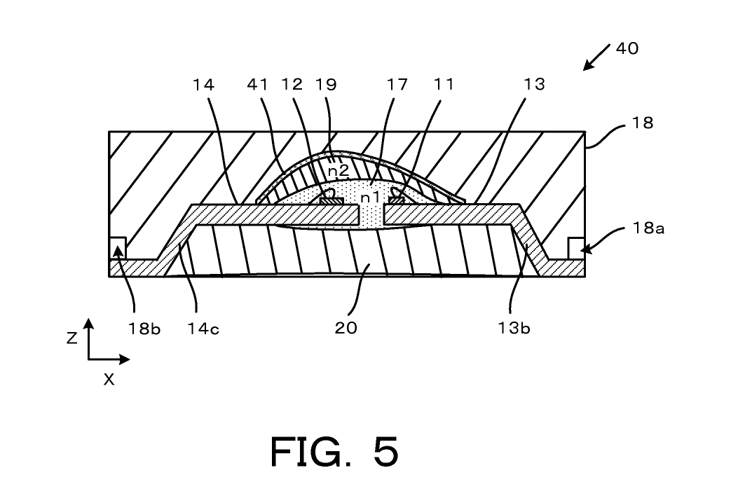

A photo coupler of a second embodiment will be described with reference to FIG. 5. FIG. 5 is a cross-sectional view illustrating the photo coupler of the second embodiment. In the second embodiment, the same portions as those in the first embodiment are denoted by the same reference numerals, and descriptions of the same portions are omitted. Only different portions will be described. The second embodiment differs from the first embodiment in that a white resin layer is provided between the second concave portion 18d of the opaque container 18 and the second translucent resin 19.

As shown in FIG. 5, in the photo coupler 40 of the second embodiment, a white resin layer 41 is provided between the second concave portion 18d of the opaque container 18 and the second translucent resin 19. The white resin layer 41 is provided so as to almost cover the entire surface of the second translucent resin 19.

The white resin layer 41 is a silicone resin which contains a large amount of particles of silica (SiO₂), for example, in such a manner as to get muddy.

Since a reflectivity of the white resin layer 41 is higher than that of opaque container 18 which is the molded body of black resin, light which is reflected with an interface between the second translucent resin 19 and the white resin layer 41 is increased. Therefore, since light which enters the light receiving device 12 is increased, it is possible to increase the light coupling efficiency.

A thickness of the white resin layer 41 is not limited in particular. However, a thickness of not less than approximately 1 μm, for example, in which a penetration of light emitted from the light emitting device 11 is negligible, is required in order to keep a reflectivity of bulk material.

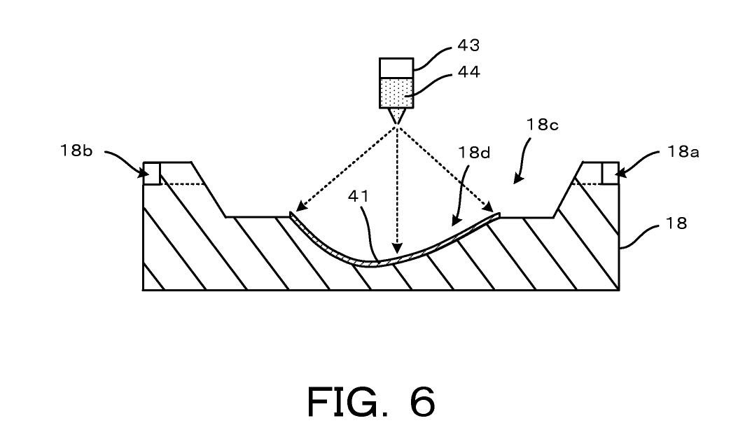

The method of manufacturing the photo coupler 40 will be described. FIG. 6 is a cross-sectional view illustrating a main step of manufacturing the photo coupler 40.

As shown in FIG. 6, a white resin 44 in liquid form is applied to the second concave portion 18d of the opaque container 18 using a sprayer 43. A cure treatment of the white resin 44 which is applied to the second concave portion 18d is performed at a prescribed temperature, so that the white resin layer 41 is obtained.

In addition, there are no problems in particular even though the white resin 44 is applied to a portion of the first concave portion 18c beyond the second concave portion 18d.

As described above, in the photo coupler 40 of the second embodiment, since the white resin layer 41 is provided between the second concave portion 18d of the opaque container 18 and the second translucent resin 19, there is an advantage that the light coupling efficiency can be increased.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A photo coupler, comprising:
a light emitting device mounted on a first mount-bed and electrically connected to a pair of first leads;
a light receiving device mounted on a second mount-bed, electrically connected to a pair of second leads, and receiving light emitted from the light emitting device by reflection;
a first resin having a first refractive index, and covering the light emitting device and the light receiving device;
an opaque container having a concave portion to store the light emitting device and the light receiving device, and reflecting the light emitted from the light emitting device at the concave portion;
a second resin having a second refractive index lower than the first refractive index, and filling a space between the first resin and the concave portion of the opaque container; and
a lid sealing the concave portion of the opaque container to store the light emitting device and the light receiving device.

2. The photo coupler according to claim 1, wherein the concave portion of the opaque container is a shape of asymmetrical dome in which a height from the light emitting device to an inner surface of the concave portion is smaller than a height from the light receiving device to the inner surface of the concave portion.

3. The photo coupler according to claim 1, wherein each of end portions of the first lead and the second lead has an upper surface, a lower surface opposed to the upper surface and an edge, the lower surface is exposed at a bottom of the opaque container, the edge is exposed at a side of the opaque container, and the bottom of the opaque container is the opening side of the concave portion of the opaque container.

4. The photo coupler according to claim 3, wherein a cutout portion to partly expose the upper surface is provided at the side of the opaque container.

5. The photo coupler according to claim 1, wherein the opaque container is a molded body of black resin.

6. The photo coupler according to claim 1, wherein the opaque container serves as a reflector which reflects the light emitted from the light emitting device to the light receiving device.

7. The photo coupler according to claim 1, wherein the lid is made of black resin.

8. The photo coupler according to claim 1, wherein the first resin and the second resin are silicone resins which differ in a quality of material.

9. The photo coupler according to claim 1, wherein the first resin and the second resin are silicone resins which are same in a quality of material, and are subjected to cure treatment at different temperatures.

10. The photo coupler according to claim 1, wherein the concave portion of the opaque container has a first concave portion having a flat bottom and a second concave portion being a shape of dome at a central portion of the first concave portion, the second resin fills a space between the first resin and the second concave portion of the opaque container, and the opaque fills the first concave portion of the opaque container.

11. A photo coupler, comprising:
a light emitting device mounted on a first mount-bed and electrically connected to a pair of first leads;
a light receiving device mounted on a second mount-bed, electrically connected to a pair of second leads, and receiving light emitted from the light emitting device by reflection;
a first resin having a first refractive index, and covering the light emitting device and the light receiving device;
an opaque container having a concave portion to store the light emitting device and the light receiving device, and reflecting the light emitted from the light emitting device at the concave portion;
a white resin layer provided on an inner surface of the concave portion and reflecting the light emitted from the light emitting device;
a second resin having a second refractive index lower than the first refractive index, and filling a space between the first resin and the white resin layer; and
a lid sealing the concave portion of the opaque container to store the light emitting device and the light receiving device.

12. The photo coupler according to claim 11, wherein the concave portion of the opaque container has a shape of asymmetrical dome in which a height from the light emitting device to the inner surface of the concave portion is smaller than a height from the light receiving device to the inner surface of the concave portion.

13. The photo coupler according to claim 11, wherein each of end portions of the first lead and the second lead has an upper surface, a lower surface opposed to the upper surface and an edge, the lower surface is exposed at a bottom of the opaque container, the edge is exposed at a side of the opaque container, and the bottom of the opaque container is the opening side of the concave portion of the opaque container.

14. The photo coupler according to claim 13, wherein a cutout portion to partly expose the upper surface is provided at the side of the opaque container.

15. The photo coupler according to claim 11, wherein the opaque container is a molded body of black resin.

16. The photo coupler according to claim 11, wherein the white resin layer has a thickness of not less than 1 μm in which a transmission of the light emitted from the light emitting device is negligible.

17. The photo coupler according to claim 11, wherein the lid is made of black resin.

18. The photo coupler according to claim 11, wherein the first resin and the second resin are silicone resins which differ in a quality of material.

19. The photo coupler according to claim 11, wherein the first resin and the second resin are silicone resins which are same in a quality of material, and are subjected to cure treatment at different temperatures.

20. The photo coupler according to claim 11, wherein the concave portion of the opaque container has a first concave portion having a flat bottom and a second concave portion being a shape of dome at a central portion of the first concave portion, the white resin layer is provided on the second concave portion of the opaque container, and the lid fills the first concave portion of the opaque container.
